(19) United States
(12) Patent Application Publication
(10) Pub. No.: US 2013/0192665 A1
(43) Pub. Date: Aug. 1, 2013

(54) ENCAPSULATION SYSTEM FOR PHOTOVOLTAIC STACK USING FIBERGLASS

(71) Applicant: PowerFilm, Inc., Ames, IA (US)

(72) Inventor: Ryan L. Jeffrey, Ames, IA (US)

(73) Assignee: POWERFILM, INC., Ames, IA (US)

(21) Appl. No.: 13/748,814

(22) Filed: Jan. 24, 2013

Related U.S. Application Data
(60) Provisional application No. 61/592,034, filed on Jan. 30, 2012.

(51) Int. Cl. H01L 31/048

(52) U.S. Cl. CPC H01L 31/0481
USPC 136/251

(57) ABSTRACT

A photovoltaic system having a plurality of photovoltaic cells electrically connected to one another with each having a substrate. An adhesive layer is presented within a fiberglass matrix such that the adhesive extends beyond to contact at least the photovoltaic cell.

### CROSS REFERENCE TO RELATED APPLICATION

This application claims the benefit of U.S. Provisional Application No. 61/592,034 filed Jan. 30, 2012.

### BACKGROUND OF THE INVENTION

This invention relates to photovoltaic cells. More specifically, this invention relates to improving flame retardancy within a photovoltaic encapsulation stack.

Advancements in solar power have caused a creation of photovoltaic stacks that are encapsulated in order to convert light energy often provided by the sun into electrical energy. In general a substrate is provided that has a plurality of photovoltaic cells that include a combination of semi conductor layer stacks with a plurality of electrodes that are able to convert solar energy into electrical energy. The cell is completed by placing a layer of adhesive on the cell that is typically made of material such as ethylvinylacetate (EVA), thermoplastic polyurethane (TPU) and polyvinylbutral (PVB) and the like to attach a protective coating over the cell. The protection coating, or top sheet, can be ethylenetetrafluoroethylene (ETFE), polyvinyldifluoride (PVDF), fluorinated ethylene-propylene (FEP), ethylene chlorotrifloroethlyene (ECTFE) or the like.

A problem exists with this system in that with a normal solar encapsulation stack when burned drops flaming bits of the adhesive which is unacceptable from a fire safety perspective. In the art, because such solar systems are desired to be used on buildings, structures and the like, there is a need to ensure that the solar system itself is flame retardant.

Therefore, an objective of the present invention is to provide a photovoltaic system that includes a fiberglass matrix for improved flame retardance and durability without losing the optical clarity of a photovoltaic cell.

This and other objectives will be apparent to one of ordinary skill in the art based upon the following written description, drawings, and claims.

### SUMMARY OF THE INVENTION

A photovoltaic system having a plurality of photovoltaic cells electrically connected to one another with each having a substrate. An adhesive layer is presented within a fiberglass matrix such that the adhesive extends beyond to contact at least the photovoltaic cell.

### BRIEF DESCRIPTION OF THE DRAWINGS

FIG. 1 is a partial side view of a photovoltaic system; and

FIG. 2 is a partial side view of a photovoltaic system.

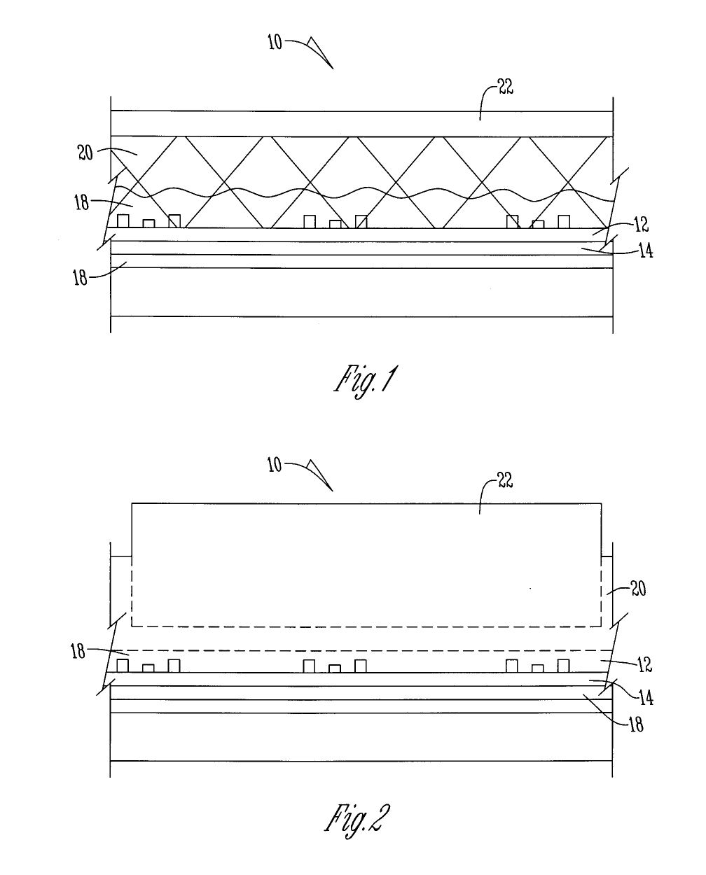

### DESCRIPTION OF THE PREFERRED EMBODIMENT

Referring to the Figures a photovoltaic system 10 is shown that presents a plurality of photovoltaic cells 12 that are electrically connected to one another. Each of the cells 12 presents a substrate 14 that receives a plurality of semi conductor layer stacks and a plurality of electrodes in order to convert solar energy into electrical energy. In the system 10 a layer of adhesive 18 is presented within a fiberglass matrix 20 in order to mechanically hold the different portions of the photovoltaic cell 12 in place even if burning. Specifically, the adhesive layer 18 comprises an adhesive such as EVA, TPU, PVB or the like dispersed within the fiberglass matrix 20 such that the fiberglass is a majority of the thickness of the adhesive layer 18 and there is just enough adhesive extending beyond the fiberglass in order to fully coat the glass fibers such that the adhesive makes solid contact with the photovoltaic cell 12 and a top sheet or coating 22. The top sheet or coating 22 can be made from ETFE, PVDF, FEP, ECTFE or the like that provides a protective layer for the photovoltaic cell 12 while allowing solar energy to pass therethrough to the electrodes and semi conductor layer stacks.

In an alternative embodiment the fiberglass matrix 20 is used to create an interface between the top layer or coating 22 and the adhesives to provide an improved mechanical bond between the adhesive 18 and the top layer 22. Specifically, a much stronger and more stable bond than a standard adhesive/fluoropolymer bond is provided. Ideally in this embodiment the top layer 22 or fluoropolymer film should extend between ½ and ¾ of the way through the thickness of the fiberglass and have 1-2 mils of thickness above the fiberglass matrix 20. Thus, the adhesive should fill the remaining portion of the fiberglass and extend just enough to create a solid surface of adhesive to bond to the face of the photovoltaic cell 12.

In operation, when the photovoltaic cell 12 is created, once the photovoltaic stack and electrodes are on a substrate, an adhesive layer 18 that presents adhesive within a fiberglass matrix 20 is adhered to thereto. At this time a top layer or coating 22 is then adhered to the adhesive layer 18 with the fiberglass matrix 20. In use the fiberglass continues to allow the solar energy or light to pass therethrough. In addition, during a fire the fiberglass holds the adhesive in place even when the adhesive burns preventing flaming bits of adhesive from dropping and creating additional fire safety issues. In this manner the fiberglass matrix 20 acts as a flame retardant for the photovoltaic cell 12.

Thus, provided is a photovoltaic system that utilizes a fiberglass matrix in order to provide improved flame retardancy and thus durability without the loss of optical clarity within the photovoltaic cell. By utilizing the fiberglass matrix an increased mechanical bond can be provided between the adhesive layer and the coating and assist in preventing the flame resistant fluoropolymer top layer or coating from melting away thus providing an opening for a path of air to be able to reach the more flammable adhesive. This improves the flame retardancy of the encapsulated system. Thus, at the very least all of the stated problems and desired needs have been met.

What is claimed is:

1. A photovoltaic system, comprising:
a plurality of photovoltaic cells that are electrically connected to one another with each having a substrate; and
an adhesive layer presented within a fiberglass matrix such that the adhesive extends beyond fiberglass to make contact with the photovoltaic cell and a top layer.

2. The system of claim 1 wherein the adhesive is dispersed within the fiberglass matrix such that the fiberglass is a majority of the thickness.

3. The system of claim 1 wherein the adhesive consists of the group of EVA, TPU, and PVB.

4. The system of claim 1 wherein the top layer consists of the group ETFE, PVDF, FEP, and ECTFE.

5. A photovoltaic system, comprising:
a plurality of photovoltaic cells that are electrically connected to one another with each having a substrate; and
a top layer partially presented within a fiberglass matrix that includes an adhesive layer that extends beyond the fiberglass matrix to contact the photovoltaic cell.

6. The system of claim 5 wherein the top layer extends between and ½ and ¾ of the thickness of the fiberglass matrix.

7. The system of claim 5 wherein the top layer extends 1-2 mils above the fiberglass matrix.

8. The system of claim 5 wherein the adhesive consists of the group of EVA, TPU, and PVB.

9. The system of claim 5 wherein the top layer consists of the group ETFE, PVDF, FEP, and ECTFE.
